(19) United States
(12) Patent Application Publication
(10) Pub. No.: US 2023/0266679 A1
(43) Pub. Date: Aug. 24, 2023

(54) Cooling system in exposure machine and the operation method thereof

(71) Applicant: United Semiconductor (Xiamen) Co., Ltd., Xiamen (CN)

(72) Inventors: YiBin Zhou, Shamen City (CN); Chiun-Show Chen, Hsinchu City (TW); Wen Yi Tan, Xiamen (CN)

(73) Assignee: United Semiconductor (Xiamen) Co., Ltd., Xiamen (CN)

(21) Appl. No.: 17/705,424

(22) Filed: Mar. 28, 2022

(30) Foreign Application Priority Data
Feb. 18, 2022 (CN) 202210149480.2

(51) Int. Cl. G03F 7/20; H05K 7/20

(52) U.S. Cl. CPC G03F 7/70891; H05K 7/20272; G03F 7/70875; G03F 7/70483

(57) ABSTRACT

The invention provides a cooling system in an exposure machine, which comprises an exposure machine for performing an exposure process of a semiconductor, at least one water storage tank, wherein the water storage tank is filled with cooling water for cooling some components of the exposure machine, a water inlet valve and a water outlet valve, which are connected with the water storage tank, and an automatic controller for controlling the water inlet valve and the water outlet valve to keep the cooling water in the water storage tank at a certain water level.

### BACKGROUND OF THE INVENTION

### 1. Field of the Invention

The invention relates to the field of semiconductor processing, in particular to an improved cooling system in a semiconductor exposure machine.

### 2. Description of the Prior Art

In the semiconductor exposure machine, some components, such as the laser transmitter, generate heat when exposing or when the stage moves. In order to avoid the influence of the generated heat energy on the accuracy of exposure, the semiconductor exposure machine will have a built-in cooling system to cool some components that are easy to generate heat energy by water cooling.

The water cooling system includes a water storage tank for storing cooling water, and the cooling water flows through the water cooling pipe to cool the components. In order to keep the water in the water storage tank at a low temperature, the water storage tank will continuously discharge water, so the cooling water in the water storage tank needs to be replenished regularly. However, at present, in the semiconductor exposure machine, the steps of observing the remaining cooling water in the water storage tank and filling water into the water storage tank for replenishment are all carried out manually, which consumes manpower. In addition, it is necessary to suspend the operation of the exposure machine when replenishing water to the water storage tank, which is not conducive to capacity production. Furthermore, if the water is not immediately replenished into the water storage tank due to the negligence of personnel, the exposure machine may be damaged.

### SUMMARY OF THE INVENTION

The invention provides a cooling system in an exposure machine, which comprises an exposure machine for performing an exposure process of a semiconductor, at least one water storage tank, wherein the water storage tank is filled with cooling water for cooling some components of the exposure machine, a water inlet valve and a water outlet valve, which are connected with the water storage tank, and an automatic controller for controlling the water inlet valve and the water outlet valve to keep the cooling water in the water storage tank at a certain water level.

The invention also provides an operation method of the cooling system in the exposure machine, which comprises providing an exposure machine for performing an exposure process of a semiconductor, providing at least one water storage tank, wherein the water storage tank is filled with cooling water for cooling some components of the exposure machine, providing a water inlet valve and a water outlet valve connected with the water storage tank, and providing an automatic controller to control the water inlet valve and the water outlet valve to keep the cooling water in the water storage tank at a certain water level.

The invention is characterize by providing an improved cooling system in a semiconductor exposure machine, wherein an automatic controller is connected with a water inlet valve and a water outlet valve in a water storage tank to automatically control that water flow into and flow out of the water storage tank, so that the water level of the water storage tank is automatically maintained within a certain range. In addition, the automatic controller of the invention can also be connected with the arithmetic processor for observing the change of water level in the water storage tank. If the water level of the water storage tank increases or decreases abnormally, the cooling system of the invention can timely find out and inform the user. In addition, the cooling system of the invention can also replenish the water level of the water storage tank on average according to the water consumption speed of the water storage tank, so as to avoid the rapid change of the temperature of the water storage tank caused by supplementing too much water level in a short time, and help to improve the yield for the process with higher accuracy requirements.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows the connection diagram of the cooling system of the semiconductor exposure machine according to the present invention.

FIG. 2 shows the data line chart of the time recorded by the arithmetic processor versus the water level of the water storage tank.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

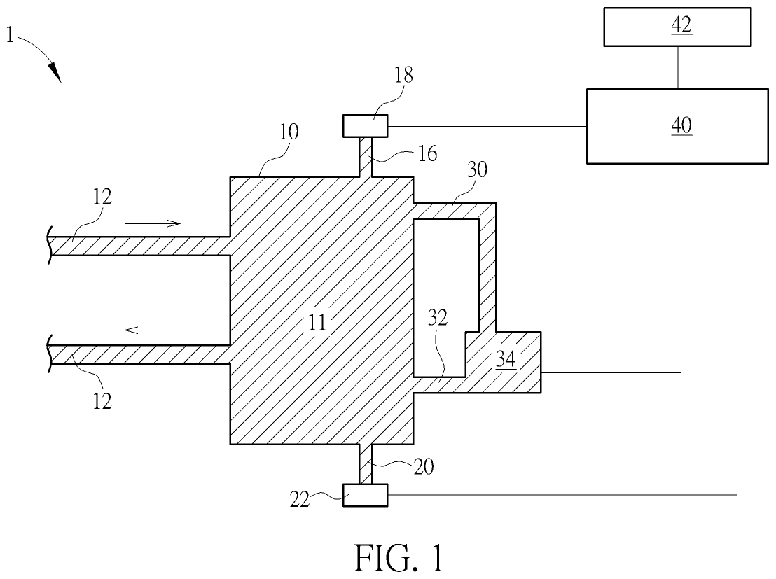

FIG. 1 shows the connection diagram of a cooling system of a semiconductor exposure machine according to the present invention. As shown in FIG. 1, the cooling system 1 of the present invention is located in a semiconductor exposure machine, in which the semiconductor machine is used for the exposure step of the semiconductor process. The cooling system 1 includes a water storage tank 10, in which cooling water 11 is stored, and one end of the water storage tank 10 is connected with a cooling loop pipe 12, in which the other end (not shown) of the two cooling loop pipes 12 form a cooling loop, that is, the ends of the two cooling loop pipes 12 shown in FIG. 1 can be connected together, and the cooling loop pipe 12 can pass through some components in the semiconductor exposure machine that need to be cooled, such as laser emitters, laser transmitter, moving stage, etc. Therefore, the cooling water 11 can flow through the cooling loop pipe 12 and then reach the components to be cooled, so that these components can be cooled by water cooling (heat exchange). Then the heated cooling water 11 will return to the water storage tank 10.

From the above steps, it is known that the cooling water 11 in the water storage tank 10 will gradually increase in temperature due to heat exchange, so it is necessary to discharge the heated cooling water 11 and inject new cooling water 11 to reduce the temperature of the cooling water 11 in the water storage tank 10 again. Therefore, as shown in FIG. 1, the water storage tank 10 is also connected with a water inlet 16 and a water outlet 20, wherein the water inlet 16 is connected with a water inlet valve 18 and the water outlet 20 is connected with a water outlet valve 22. When the water inlet valve 18 is open, new cooling water 11 can be injected into the water storage tank 10 through the water inlet 16, while when the water inlet valve 18 is closed, the injection of new cooling water 11 into the water storage tank 10 is stopped. On the other hand, when the water outlet valve 22 is open, the old cooling water 11 in the water storage tank 10 can flow out through the water outlet 20, while when the water outlet valve 22 is closed, the cooling water 11 in the water storage tank 10 stops flowing out. By opening or closing the water inlet valve 18 and the water outlet valve 22, the amount of water in the water storage tank 10 can be controlled. In addition, in order to allow the cooling water 11 in the water storage tank 10 to immediately flow out of the water storage tank 10 and avoid excessive accumulation of high-temperature water in the water storage tank 10, the water outlet valve 22 can be preset to open, that is, when the cooling system 1 is in operation, the water level in the water storage tank 10 will gradually decrease, and new water needs to be regularly added to the water storage tank 10.

In the conventional semiconductor exposure machine, the steps of observing the remaining water in the water storage tank 10, controlling the water inlet valve 18 and the water outlet valve 22, etc. are all performed by manpower. Therefore, not only this process will consume manpower, but also the operation of the exposure machine needs to be suspended during water injection and water discharge, which is not conducive to the production efficiency. Besides, if the cooling water is not replenished to the water storage tank in time due to negligence of personnel, the machine may be damaged.

Therefore, the cooling system 1 provided by the present invention improves the above shortcomings. The cooling system 1 of the present invention also includes an upper water pipe 30 and a lower water pipe 32 connected with the water storage tank 10, and a hydraulic detector 34 is also included between the upper water pipe 30 and the lower water pipe 32. The upper water pipe 30 and the lower water pipe 32 are connected to the upper and lower parts of the water storage tank 10 respectively, and the hydraulic detector 34 is arranged between the upper water pipe 30 and the lower water pipe 32, which is used to measure the hydraulic pressure difference between the upper water pipe 30 and the lower water pipe 32, and then calculate the remaining water amount in the water storage tank 10. Therefore, the water level of the water storage tank 10 can be known by reading the value of the hydraulic detector 34, and the water level value can be obtained without observing the water level by manpower or suspending the operation of the exposure machine.

The water inlet valve 18 and the water outlet valve 22 of the cooling system 1 of the present invention are both electronic switches, which can be controlled to be opened or closed by electrical signals. The cooling system 1 of the present invention further comprises an automatic controller 40, the automatic controller 40 is connected with the hydraulic detector 34, the water inlet valve 18 and the water outlet valve 22. The automatic controller 40 can be used to read the water level of the hydraulic detector 34 and determine whether the current water level in the water storage tank 10 is within a certain range. If the water level in the water storage tank 10 is too low, the water inlet valve 18 is opened and the water outlet valve 22 is closed to raise the water level in the water storage tank 10 until the water level in the water storage tank 10 returns to normal. On the other hand, if the water level of the water storage tank 10 is too high, the water inlet valve 18 is closed and the water outlet valve 22 is opened to lower the water level of the water storage tank 10 until the water level of the water storage tank 10 returns to normal. In addition, when the water level is too high or too low, the cooling system 1 can also give an alarm to notify the user.

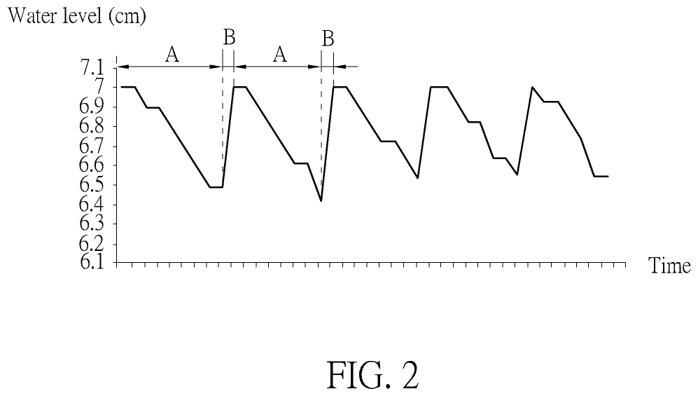

In addition, the automatic controller 40 of the present invention is also connected with an arithmetic processor 42, wherein the function of the arithmetic processor 42 is to record, calculate or draw graphs or tables according to the detected data, such as a statistical process control (SPC) system. The arithmetic processor 42 of the present invention can be used, for example, to record the water level data in the water storage tank 10, and determine whether there is an abnormal issue according to the change amount of the water level. For example, FIG. 2 shows a data line chart of the time recorded by the arithmetic processor versus the water level of the water storage tank. As shown in FIG. 2, the horizontal axis represents time, and the unit can be seconds, minutes or hours, while the vertical axis represents the water level in the water storage tank, and the unit is centimeters (cm), for example, but not limited to this. As shown in FIG. 2, because the water outlet valve 22 is opened by default, the water level in the water storage tank 10 will decrease with the passage of time (as shown in stage A in FIG. 2), and when the water level drops to a certain degree, it is necessary to replenish water to the water storage tank 10 (as shown in stage B in FIG. 2). It should be noted that although the water level in FIG. 2 varies in the range of 6-7 cm, the above numerical value is only one example of the present invention, and the present invention is not limited by it. Using the arithmetic processor 42 to record and draw the water level in the water storage tank 10 can be convenient for users to observe whether the cooling system maintains normal operation, and it is easier for users to find out the problem in time when there is a problem with the inlet and outlet water. For example, the user can observe the slope of stage A or stage B. If the slope of stage A becomes larger, it means that there is abnormal water leakage in the water storage tank 10 (for example, the water outlet valve 22 is excessively opened or the water storage tank 10 leaks), and if the slope of stage B is too small, it may also mean abnormal water inlet function or insufficient water inlet. Drawing and observing the water level of the water storage tank 10 by the arithmetic processor 42 is helpful for users to find problems in time and take corresponding remedial measures against them during the operation of the cooling system 1.

In addition, the applicant also found that the rate of water injection added to the water storage tank 10 also affects the temperature of the whole water storage tank 10. In the known technology, because water is injected by manpower, a large amount of water is usually injected in a short time. The applicant found that if a large amount of water was added to the water storage tank 10 in a short time, the temperature in the water storage tank 10 would change greatly. This may affect the quality of some exposure processes (especially those with higher precision requirements). Therefore, the cooling system 1 of the present invention can replace manpower for water injection in an automatic way, and can also carry out reasonable water injection and water discharge distribution according to the analysis result of the arithmetic processor 42 (for example, FIG. 2), which is beneficial to improve the quality of the manufacturing process. In addition, in order to accurately maintain the temperature in the water storage tank 10, a thermometer (not shown) can be added to measure the temperature in the water storage tank 10, and the numerical value of the thermometer can be recorded by the arithmetic processor 42. At the same time, the rate of water injection and water discharge can be controlled by the automatic controller 40 to maintain the temperature and achieve a better constant temperature effect. The above features also fall within the scope of the present invention.

According to the conventional procedure, the water in the water storage tank 10 is replenished manually, so the operation of the exposure machine must be suspended when the water is replenished. The invention controls water injection and water discharge in an automatic way, so there is no need to suspend the operation of the exposure machine. That is to say, the steps of water injection or water discharge can be carried out at the same time as the exposure process of the exposure machine, so that the production can be improved.

According to the above description and drawings, the present invention provides a cooling system 1 in an exposure machine, which comprises an exposure machine for performing an exposure process of a semiconductor, at least one water storage tank 10, cooling water 11 in the water storage tank 10 for cooling some components of the exposure machine, a water inlet valve 18 and a water outlet valve 22 connected to the water storage tank, and an automatic controller 40 for controlling the water inlet valve 18 and the water outlet valve 22 to keep the cooling water 11 in the water storage tank 10.

In some embodiments of the present invention, it further includes a cooling loop pipe 12. After the cooling water 11 enters the cooling loop pipe 12, it is used to cool a laser transmitter (not shown) and a moving stage (not shown) in the exposure machine.

In some embodiments of the present invention, a hydraulic detector 34 is further included, which connects the upper water pipe 30 and the lower water pipe 32 of the water storage tank 10 and is used to detect the water level of the cooling water 11 in the water storage tank 10.

In some embodiments of the present invention, the hydraulic detector 34 is connected with the automatic controller 40 to transmit a plurality of signals to the automatic controller 40.

In some embodiments of the present invention, the automatic controller 40 is further connected with an arithmetic processor 42 to make a graph of a plurality of signals from the hydraulic detector 34 (as shown in FIG. 2).

In some embodiments of the present invention, the automatic controller 40 opens or closes the water inlet valve 18 or the water outlet valve 22 according to signals from the hydraulic detector 34 to control the cooling water 11 to flow into or out of the water storage tank 10.

The invention also provides an operation method of the cooling system in the exposure machine, which includes providing an exposure machine for performing a semiconductor exposure process, providing at least one water storage tank 10 with cooling water 11 for cooling some components of the exposure machine, providing a water inlet valve 18 and a water outlet valve 22, connecting the water storage tank 10, and providing an automatic controller 40 to control the water inlet valve 18 and the water outlet valve 22 to make the cooling water 11 in the water storage tank 10

In some embodiments of the present invention, the arithmetic processor 42 determines whether a slope of the graph (as shown in FIG. 2) is within an allowable range (a certain range), and if the slope of the graph is not within the allowable range, the arithmetic processor issues an alarm.

In some embodiments of the present invention, the process of the cooling water 11 flowing into or out of the water storage tank 10 is carried out at the same time as the semiconductor exposure process of the exposure machine (that is, the semiconductor exposure machine can inject or drain water without stopping the machine).

The invention is characterize by providing an improved cooling system in a semiconductor exposure machine, wherein an automatic controller is connected with a water inlet valve and a water outlet valve in a water storage tank to automatically control that water flow into and flow out of the water storage tank, so that the water level of the water storage tank is automatically maintained within a certain range. In addition, the automatic controller of the invention can also be connected with the arithmetic processor for observing the change of water level in the water storage tank. If the water level of the water storage tank increases or decreases abnormally, the cooling system of the invention can timely find out and inform the user. In addition, the cooling system of the invention can also replenish the water level of the water storage tank on average according to the water consumption speed of the water storage tank, so as to avoid the rapid change of the temperature of the water storage tank caused by supplementing too much water level in a short time, and help to improve the yield for the process with higher accuracy requirements.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A cooling system in an exposure machine, comprising:
an exposure machine for performing an exposure process of a semiconductor;
at least one water storage tank filled with cooling water for cooling some components of the exposure machine;
a water inlet valve and a water outlet valve connected to the water storage tank; and
an automatic controller controls the water inlet valve and the water outlet valve to keep the cooling water in the water storage tank at a certain water level.

2. The cooling system in the exposure machine according to claim 1, further comprising a cooling loop pipe, wherein the cooling water is used to cool a laser transmitter and a moving stage in the exposure machine after entering the cooling loop pipe.

3. The cooling system in the exposure machine according to claim 1, further comprising a hydraulic detector connected to the water storage tank and used for detecting the water level of the cooling water in the water storage tank.

4. The cooling system in the exposure machine according to claim 3, wherein the hydraulic detector is connected with the automatic controller to transmit a plurality of signals to the automatic controller.

5. The cooling system in the exposure machine according to claim 4, wherein the automatic controller is further connected with an arithmetic processor to make a graph of the signals from the hydraulic detector.

6. The cooling system in the exposure machine according to claim 3, wherein the automatic controller opens or closes the water inlet valve or the water outlet valve according to the signals from the hydraulic detector to control the cooling water to flow into or out of the water storage tank.

7. A method for operating a cooling system in an exposure machine, comprising:
providing an exposure machine for exposing a semiconductor;
providing at least one water storage tank filled with cooling water for cooling some components of the exposure machine;
providing a water inlet valve and a water outlet valve connected with the water storage tank; and
providing an automatic controller to control the water inlet valve and the water outlet valve to keep the cooling water in the water storage tank at a certain water level.

8. The operation method of the cooling system in the exposure machine according to claim 7, further comprising providing a cooling loop pipe, and cooling water is used to cool a laser transmitter and a moving stage in the exposure machine after entering the cooling loop pipe.

9. The operation method of the cooling system in the exposure machine according to claim 7, further comprising providing a hydraulic detector connected to the water storage tank and used for detecting the water level of the cooling water in the water storage tank.

10. The operation method of the cooling system in the exposure machine according to claim 9, wherein the hydraulic detector is connected with the automatic controller to transmit a plurality of signals to the automatic controller.

11. The operation method of the cooling system in the exposure machine according to claim 10, wherein the automatic controller is further connected with an arithmetic processor to make a graph of the signals from the hydraulic detector.

12. The operation method of the cooling system in the exposure machine according to claim 11, wherein the arithmetic processor determines whether a slope of the graph is within an allowable range, and if the slope of the graph is not within the allowable range, the arithmetic processor sends an alarm.

13. The operation method of the cooling system in the exposure machine according to claim 9, wherein the automatic controller opens or closes the water inlet valve or the water outlet valve according to the signals from the hydraulic detector to control the cooling water to flow into or out of the water storage tank.

14. The operation method of the cooling system in the exposure machine according to claim 13, wherein the process of the cooling water flowing into or out of the water storage tank is simultaneously performed with the exposure process of the semiconductor in the exposure machine.
